(19) United States
(12) Patent Application Publication
(10) Pub. No.: US 2026/0044643 A1
(43) Pub. Date: Feb. 12, 2026

(54) RECORDING MEDIUM, INFORMATION PROCESSING METHOD, AND INFORMATION PROCESSING DEVICE

(71) Applicant: Fujitsu Limited, Kawasaki-shi (JP)

(72) Inventor: Yosuke OYAMA, Kawasaki (JP)

(73) Assignee: Fujitsu Limited, Kawasaki-shi (JP)

(21) Appl. No.: 19/359,964

(22) Filed: Oct. 16, 2025

Related U.S. Application Data
(63) Continuation of application No. PCT/JP2024/009465, filed on Mar. 12, 2024.

(30) Foreign Application Priority Data
Apr. 26, 2023 (JP) 2023-072807

(51) Int. Cl. G06F 30/20

(52) U.S. Cl. CPC G06F 30/20

(57) ABSTRACT

A computer-readable recording medium stores therein an information processing program causing a computer to execute a process, the process including: obtaining one or more candidates for a setting value related to an execution environment for parallel processing of a density functional theory calculation for a substance; calculating a sum of costs for each of the obtained one or more candidates, the sum of costs being calculated based on one or more model expressions that, respectively, correspond to one or more calculation processes related to the density functional theory calculation and that, respectively, output an estimated value of a cost incurred when a corresponding one of the one or more calculation processes is performed in response to input of the setting value; and determining the setting value based on the sum calculated for the each of the obtained one or more candidates.

### CROSS REFERENCE TO RELATED APPLICATIONS

This is a continuation application of International Application PCT/JP2024/009465 filed on Mar. 12, 2024 which claims priority from a Japanese Patent Application No. 2023-072807 filed on Apr. 26, 2023, the contents of which are incorporated herein by reference.

### FIELD

The embodiments discussed herein are related to a recording medium, an information processing method, and an information processing device.

### BACKGROUND

In fields such as materials engineering, materials science, and materials development, parallel processing of density functional theory calculations on substances is sometimes used to analyze the ground-state energy of a substance or changes in energy due to the displacement of atoms within a substance.

One prior art, for example, according to performance requirements of a lubricant, uses atomistic modeling tools to design lubricant formulations that substantially satisfy a set of performance requirements of the lubricant. For example, refer to Published Japanese-Translation of PCT Application, Publication No. 2008-523472

### SUMMARY

According to an aspect of an embodiment, a computer-readable recording medium stores therein an information processing program causing a computer to execute a process, the process including: obtaining one or more candidates for a setting value related to an execution environment for parallel processing of a density functional theory calculation for a substance; calculating a sum of costs for each of the obtained one or more candidates, the sum of costs being calculated based on one or more model expressions that, respectively, correspond to one or more calculation processes related to the density functional theory calculation and that, respectively, output an estimated value of a cost incurred when a corresponding one of the one or more calculation processes is performed in response to input of the setting value; and determining the setting value based on the sum calculated for the each of the obtained one or more candidates.

An object and advantages of the disclosure will be realized and attained by means of the elements and combinations particularly pointed out in the claims.

It is to be understood that both the foregoing general description and the following detailed description are exemplary and explanatory and are not restrictive of the disclosure.

### BRIEF DESCRIPTION OF DRAWINGS

FIG. 1 is an explanatory diagram depicting one example of an information processing method according to an embodiment.

FIG. 2 is an explanatory diagram depicting an example of an information processing system 200.

FIG. 3 is a block diagram of an example of a hardware configuration of an information processing device 100.

FIG. 4 is a block diagram depicting an example of a functional configuration of the information processing device 100.

FIG. 5 is an explanatory diagram depicting an example of operation of the information processing device 100.

FIG. 6 is an explanatory diagram depicting an example of the operation of the information processing device 100.

FIG. 7 is an explanatory diagram depicting an example of the operation of the information processing device 100.

FIG. 8 is an explanatory diagram depicting an example of the operation of the information processing device 100.

FIG. 9 is an explanatory diagram depicting an example of the operation of the information processing device 100.

FIG. 10 is an explanatory diagram depicting a specific example of the operation of the information processing device 100.

FIG. 11 is an explanatory diagram depicting a specific example of the operation of the information processing device 100.

FIG. 12 is an explanatory diagram depicting an embodiment of the information processing device 100.

FIG. 13 is a flowchart depicting an example of an overall processing procedure.

FIG. 14 is a flowchart depicting an example of the overall processing procedure.

### DESCRIPTION OF EMBODIMENTS

First, problems associated with the conventional techniques are discussed. With the prior art, it is difficult to reduce the cost of parallel processing of the density functional theory calculations on substances. For example, it is not possible to determine the optimal number of nodes for parallel processing of the density functional theory calculations on a substance.

Embodiments of a computer-readable recording medium, an information processing method, and an information processing device according to the present disclosure are described in detail with reference to the accompanying drawings.

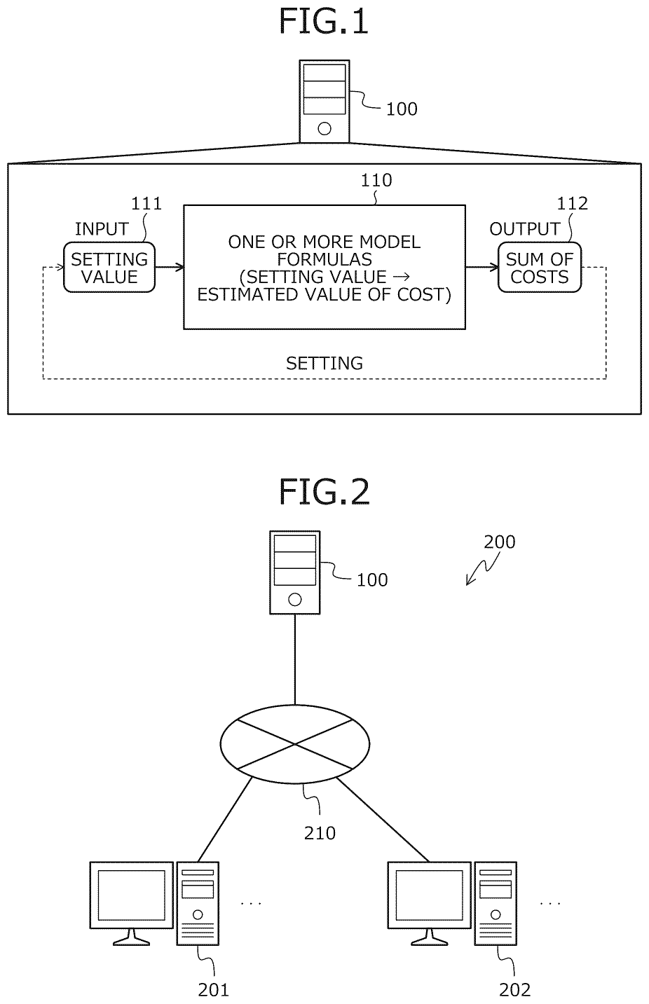

FIG. 1 is an explanatory diagram depicting one example of an information processing method according to an embodiment. An information processing device 100 is a computer that facilitates parallel processing of density functional theory calculations for substances. The information processing device 100 is, for example, a server or a personal computer (PC).

Conventionally, in fields such as materials engineering, materials science, and materials development, it is desirable to verify the physical properties, etc. of substances. Examples of such substances include materials. For example, verifying the physical properties of materials is desirable for the design, research, or development of practical materials. Examples of such materials include catalysts.

Here, for example, it is conceivable to verify the physical properties of a material by manufacturing an actual material and conducting predetermined experiments on the actual material. However, this method entails problems such as increased manpower, time, and financial costs occurring when verifying the physical properties, etc. of a material. Furthermore, specifically, another problem is the difficulty in accurately manufacturing an actual material in a desired state in order to verify the physical properties, etc. of the material in a different state.

For this reason, simulations to verify the physical properties, etc. of a substance tend to be desirable. Density functional theory calculations for substances are used in simulations. For example, when performing a simulation, density functional theory calculations may be performed on a substance to analyze the ground state energy of the substance or changes in energy due to the displacement of atoms within the substance. For example, it is conceivable to perform density functional theory calculations on a substance to calculate the energy used in a chemical reaction at the surface of the substance and then perform a simulation to verify the rate of the chemical reaction.

Here, the larger the scale of a substance, the longer the processing time necessary to perform density functional theory calculations for the substance tends to be. The scale of a substance may include, for example, 10,000 atoms. For example, for a given number of atoms, N, the calculational complexity of density functional theory calculations for a substance is O(N\hat{ }3). Furthermore, when performing a simulation to verify the physical properties of multiple substances, density functional theory calculations are performed for each of the substances. Thus, density functional theory calculations for substances may become a bottleneck when verifying the physical properties, etc. of materials.

Therefore, parallel processing of density functional theory calculations for substances is sometimes desirable. However, with the conventional methods, a problem arises in that it is difficult to reduce the time, power, and/or monetary costs involved in parallel processing density functional theory calculations for substances.

For example, there is a problem in that it is impossible to determine how many nodes are desirable for parallel processing of density functional theory calculations for substances. For example, there is a problem in that it is impossible to determine how many nodes, processes, or threads are desirable for parallel processing of density functional theory calculations for substances.

For example, it is conceivable for an operator to determine how many nodes are desirable for parallel processing of density functional theory calculations for substances, but this increases the workload on the operator. Furthermore, specifically, unless an operator is familiar with density functional theory calculations for substances, it is difficult to appropriately determine the number of nodes on which density functional theory calculations for substances are to be processed in parallel.

Parallel processing of density functional theory calculations for substances without determining the number of nodes on which density functional theory calculations for substances are to be processed in parallel results in increased time, power, and monetary costs.

Therefore, in this embodiment, an information processing method that may reduce the cost of parallel processing density functional theory calculations for substances is described. In the following description, density functional theory may be referred to as “density functional theory (DFT)”. Furthermore, in the following description, DFT may also refer to hybrid DFT.

In FIG. 1, the information processing device 100 stores a model expression 110 corresponding to each of one or more calculation processes related to DFT calculations for substances. The DFT calculation for a substance is defined, for example, by a combination of predetermined attribute values. The predetermined attribute values are, for example, set in advance by a user.

The attribute values include, for example, the type of atoms forming the substance, the number of atoms forming the substance, the positions of the atoms forming the substance, the type of density functional for the substance, the type of basis function used in the density functional for the substance, or the termination condition for the DFT calculation for the substance.

The model expression 110 corresponding to any of the calculation processes has a function of outputting an estimated value of the cost necessary to perform the any of the calculation processes in response to, for example, input of a setting value 111 related to an execution environment for parallel processing of the DFT calculation for the substance. The cost is, for example, a time, power, or monetary cost. The setting value 111 is, for example, the number of processes for parallel processing of the DFT calculation for the substance, or the number of threads within a process. The setting value 111 is, for example, a combination of the number of processes and the number of threads within a process.

(1-1) The information processing device 100 obtains one or more candidates for the setting value 111 related to an execution environment for parallel processing of DFT calculations for a substance. A candidate is, for example, an example of a combination of the number of processes and the number of threads within the process. The information processing device 100 obtains one or more candidates for the setting value 111 by receiving input of one or more candidates for the setting value 111 based on a user's operation input.

(1-2) The information processing device 100 calculates a sum 112 of costs for each of the obtained one or more candidates based on the corresponding model expressions 110. For example, the information processing device 100 obtains, for each candidate, estimated values of the costs output by the model expressions 110 respectively corresponding to the calculation processes. For example, the information processing device 100 calculates the sum 112 by adding up the obtained costs for each candidate. This enables the information processing device 100 to evaluate how desirable each candidate is in terms of the cost necessary for parallel processing of DFT calculations for a substance.

(1-3) The information processing device 100 determines the setting value 111 based on the calculated sum 112. For example, the information processing device 100 determines, as the setting value 111, one of the one or more candidates whose calculated sum 112 is the smallest. For example, the information processing device 100 may determine, as the setting value 111, one of the one or more candidates whose calculated sum 112 is not more than a threshold. For example, the information processing device 100 may determine, as the setting value 111, the statistical value of the one or more candidates whose calculated sum 112 is not more than a threshold.

This allows the information processing device 100 to appropriately set the setting value 111 in terms of the cost necessary for parallel processing of DFT calculations for a substance. The information processing device 100 may reduce the cost necessary for parallel processing of DFT calculations for a substance. As a result, the information processing device 100 may easily perform simulations to verify the physical properties of a substance.

Here, while a case where the predetermined attribute values are set in advance by the user has been described, this is not a limitation. For example, the information processing device 100 may also receive input of a combination of predetermined attribute values. In this case, the information processing device 100 may generate the model expression 110 corresponding to each of one or more calculation processes related to a DFT calculation for a substance, the calculation process being defined by the combination of predetermined attribute values that has been received as input.

Here, while a case where the functions of the information processing device 100 are implemented by a single computer has been described, this is not a limitation. For example, the functions of the information processing device 100 may be implemented by multiple computers working together. For example, the functions of the information processing device 100 may be implemented on the cloud.

Next, an example of an information processing system 200 to which the information processing device 100 depicted in FIG. 1 is applied will be described with reference to FIG. 2.

FIG. 2 is an explanatory diagram depicting an example of the information processing system 200. In FIG. 2, the information processing system 200 includes the information processing device 100, one or more parallel processing devices 201, and one or more client apparatuses 202.

In the information processing system 200, the information processing device 100 and the parallel processing devices 201 are connected via a wired or wireless network 210. The network 210 may be, for example, a local area network (LAN), a wide area network (WAN), or the Internet. In the information processing system 200, the information processing device 100 and the client apparatus 202 are connected via the wired or wireless network 210.

The information processing device 100 is a computer that facilitates parallel processing of DFT calculations for substances. The information processing device 100 receives a processing request from the client apparatus 202 requesting parallel processing of DFT calculations for substances. The processing request includes, for example, a combination of predetermined attribute values. The processing request includes, for example, one or more candidate setting values related to the execution environment of the DFT calculations for the substances.

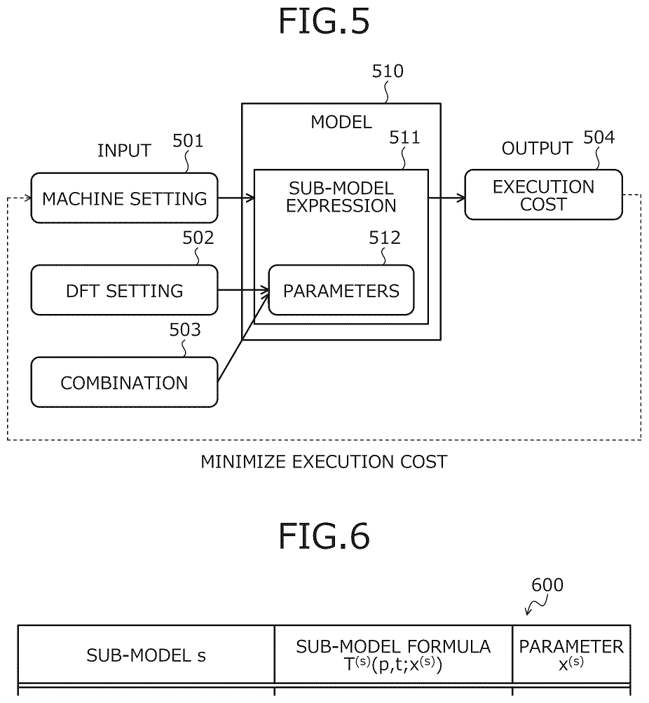

The information processing device 100 obtains a combination of predetermined attribute values from the processing request. The information processing device 100 generates a model expression corresponding to each of one or more calculation processes related to the DFT calculations for the substances, which are defined by the obtained combination of predetermined attribute values. Specific examples of generating a model expression will be described later, for example, with reference to FIGS. 5 to 12.

The information processing device 100 obtains, from the processing request, one or more candidate setting values related to the execution environment of the DFT calculation for the substance. Similar to FIG. 1, the information processing device 100 calculates the sum of costs corresponding to each of the obtained one or more candidates based on the model expression. Similar to FIG. 1, the information processing device 100 determines the setting value based on the calculated sum.

The information processing device 100 controls the one or more parallel processing devices 201 based on the determined setting value to perform parallel processing of the DFT calculation for the substance. As a result of controlling the one or more parallel processing devices 201, the information processing device 100 obtains the results of the parallel processing of the DFT calculation for the substance. The information processing device 100 transmits the results of the parallel processing of the DFT calculation for the substance to the client apparatus 202. The information processing device 100 is, for example, a server or a PC.

The parallel processing device 201 is a computer for performing parallel processing of DFT calculations for substances. The parallel processing device 201 shares the DFT calculations for substances under the control of the information processing device 100. The parallel processing device 201 is, for example, a server or a PC.

The client apparatus 202 is a computer used by an operator attempting to verify the physical properties of a substance. The client apparatus 202 receives input of a combination of predetermined attribute values based on operational input by the operator. The client apparatus 202 receives input of one or more candidate setting values related to the execution environment of the DFT calculations for the substance based on operational input by the operator.

The client apparatus 202 generates a processing request including the combination of predetermined attribute values for which input has been received and one or more candidate setting values related to the execution environment of the DFT calculations for the substance for which input has been received. The client apparatus 202 transmits the generated processing request to the information processing device 100.

The client apparatus 202 receives the results of the parallel processing of the DFT calculations for the substance from the information processing device 100. The client apparatus 202 outputs the results of the parallel processing of the DFT calculations for the substance so that the operator may refer to the results. The client apparatus 202 is, for example, a PC, a tablet terminal, or a smartphone.

Here, while a case where the information processing device 100 is a computer different from the parallel processing device 201 has been described, this is not a limitation. For example, the information processing device 100 may have the functions of the parallel processing device 201 and operate as the parallel processing device 201.

Here, while a case where the information processing device 100 is a computer different from the client apparatus 202 has been described, this is not a limitation. For example, the information processing device 100 may have the functions of the client apparatus 202 and operate as the client apparatus 202.

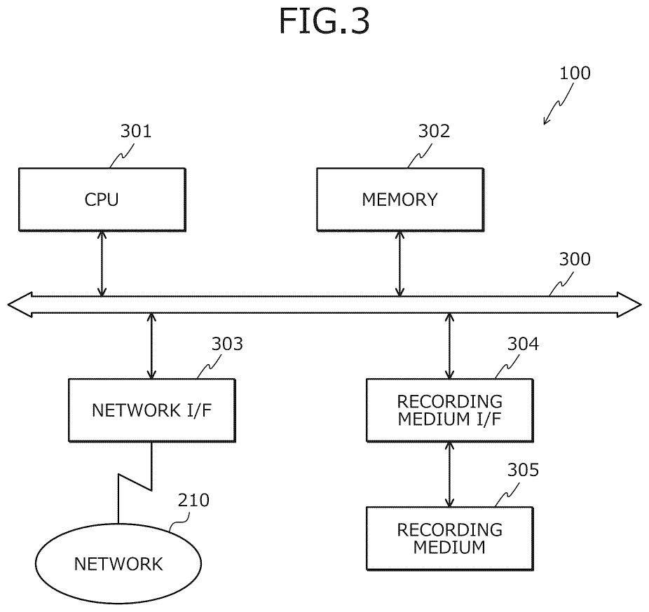

Next, an example of a hardware configuration of the information processing device 100 is described with reference to FIG. 3.

FIG. 3 is a block diagram of an example of a hardware configuration of the information processing device 100. In FIG. 3, the information processing device 100 has a central processing unit (CPU) 301, a memory 302, a network interface (I/F) 303, a recording medium I/F 304, and a recording medium 305. Further, the components are connected to each other by a bus 300.

Here, the CPU 301 governs overall control of the information processing device 100. The memory 302, for example, includes a read-only memory (ROM), a random access memory (RAM), and a flash-ROM. In particular, for example, the flash-ROM and/or ROM stores therein various programs and the RAM is used as a work area of the CPU 301. Programs stored to the memory 302 are loaded onto the CPU 301, whereby encoded processes are executed by the CPU 301.

The network I/F 303 is connected to the network 210 via a communications line and is connected to other computers through the network 210. Further, the network I/F 303 administers an internal interface with the network 210 and controls the input and output of data with respect to the other computers. The network I/F 303, for example, is a modem, a LAN adapter, or the like.

The recording medium I/F 304 controls the reading and writing of data with respect to the recording medium 305 under the control of the CPU 301. The recording medium I/F 304 is, for example, a disc drive, a solid-state drive (SSD), a universal serial bus (USB) port, or the like. The recording medium 305 is a nonvolatile memory storing data written thereto under the control of the recording medium I/F 304. The recording medium 305 is, for example, a disc, a semiconductor memory, a USB memory, or the like. The recording medium 305 may be removable from the information processing device 100.

In addition to the components above, the information processing device 100 may include, for example, a keyboard, a mouse, a display, a printer, a scanner, a microphone, a speaker, etc. Further, the information processing device 100 may further have the recording medium I/F 304 and/or the recording medium 305 in plural. The information processing device 100 may omit the recording medium I/F 304 and/or the recording medium 305.

An example of a hardware configuration of the parallel processing device 201 is the same as the example of the hardware configuration of the information processing device 100 depicted in FIG. 3 and thus, description thereof is omitted herein.

An example of a hardware configuration of the client device 202 is the same as the example of the hardware configuration of the information processing device 100 depicted in FIG. 3 and thus, description thereof is omitted herein.

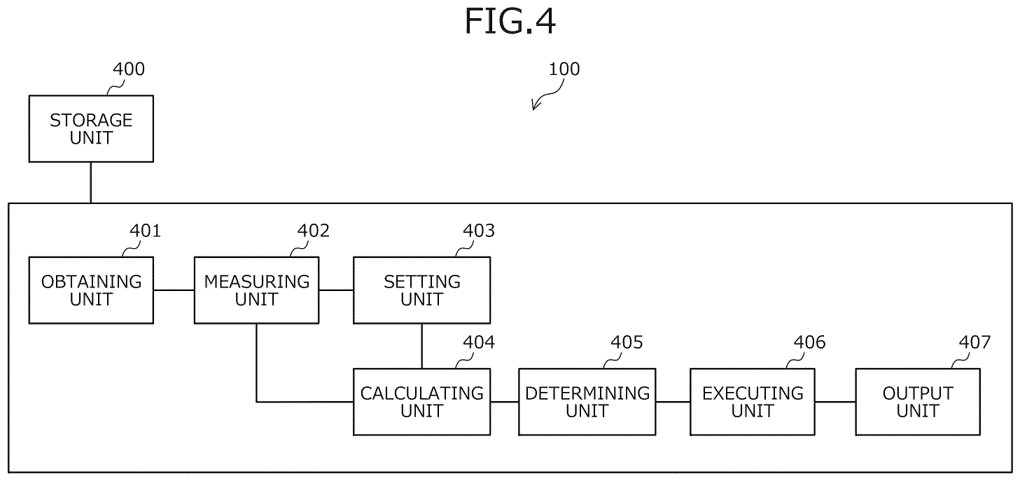

Next, an example of a functional configuration of the information processing device 100 will be described with reference to FIG. 4.

FIG. 4 is a block diagram depicting an example of the functional configuration of the information processing device 100. The information processing device 100 includes a storage unit 400, an obtaining unit 401, a measuring unit 402, a setting unit 403, a calculating unit 404, a determining unit 405, an executing unit 406, and an output unit 407.

The storage unit 400 is implemented, for example, by a storage area such as the memory 302 or the recording medium 305 depicted in FIG. 3. While the following describes a case where the storage unit 400 is included in the information processing device 100, but this is not a limitation. For example, the storage unit 400 may be included in a device different from the information processing device 100, and the contents stored in the storage unit 400 may be accessible from the information processing device 100.

The obtaining unit 401 to the output unit 407 function as an example of a control unit. For example, functions of the obtaining unit 401 to the output unit 407 are implemented by, for example, causing the CPU 301 execute a program stored in a storage area such as the memory 302 or the recording medium 305 depicted in FIG. 3, or by using a network I/F 303. The processing results of each functional unit are stored to a storage area such as the memory 302 or the recording medium 305 depicted in FIG. 3.

The storage unit 400 stores various information referenced or updated in the processes of the functional units. The storage unit 400 stores, for example, one or more attribute values that define DFT calculations for a substance. The attribute values indicate, for example, the type of atoms that form the substance, the number of atoms that form a substance, or the positions of the atoms that form a substance. The attribute values indicate, for example, the type of density functional for a substance, or the type of basis function used in the density functional for a substance. The attribute values indicate, for example, the termination conditions for DFT calculations for a substance. The attribute values are, for example, set in advance by a user. The attribute values are obtained by, for example, the obtaining unit 401.

The storage unit 400 stores, for example, one or more samples of setting values related to an execution environment for parallel processing of DFT calculation for a substance. The setting values are, for example, information specifying the number of processes sharing the DFT calculations for substances and the number of threads each process has. The setting values are, for example, a combination of the number of processes and the number of threads in each process. The samples are, for example, set in advance by a user. The samples are obtained by, for example, the obtaining unit 401.

The storage unit 400 stores, for example, one or more candidates of setting values related to an execution environment for parallel processing of DFT calculations for substances. The candidates are, for example, set in advance by a user. The candidates are obtained by, for example, the obtaining unit 401.

The storage unit 400 stores, for example, model expressions corresponding to each of one or more calculation processes related to DFT calculations for substances. The model expression corresponding to any of the calculation processes has a function of outputting an estimated value of the cost necessary to perform any of the calculation processes, for example, in response to input of setting values related to an execution environment for parallel processing of DFT calculations for a substance. The cost may be, for example, a time cost, a power cost, or a monetary cost. The model expression is obtained, for example, by the obtaining unit 401. The model expression is generated, for example, by the setting unit 403.

The obtaining unit 401 obtains various information used in the processes of the functional units. The obtaining unit 401 stores the obtained various information to the storage unit 400 or outputs the obtained information to the functional units. The obtaining unit 401 may also output various information stored in the storage unit 400 to the functional units. The obtaining unit 401 obtains various information, for example, based on a user's operation input. The obtaining unit 401 may receive various information, for example, from a device other than the information processing device 100.

The obtaining unit 401 obtains, for example, a processing request requesting parallel processing of DFT calculations for a substance. For example, the obtaining unit 401 obtains the processing request by receiving input of the processing request based on a user's operation input. For example, the obtaining unit 401 obtains the processing request by receiving the processing request from another computer. The other computer is, for example, the client apparatus 202.

The processing request may include, for example, one or more attribute values that define the DFT calculations for the substance. The processing request may include, for example, one or more examples of setting values related to an execution environment for parallel processing of the DFT calculations for the substance. The processing request may include, for example, one or more candidates for setting values related to an execution environment for parallel processing of the DFT calculations for the substance. The processing request may include, for example, a model expression corresponding to each of one or more calculation processes related to the DFT calculations for the substance.

The obtaining unit 401 obtains, for example, one or more attribute values that define the DFT calculations for the substance. For example, the obtaining unit 401 obtains one or more attribute values by receiving input of one or more attribute values based on operation input by a user. For example, the obtaining unit 401 obtains one or more attribute values by receiving the one or more attribute values from another computer. The other computer is, for example, the client apparatus 202. For example, the obtaining unit 401 obtains one or more attribute values by extracting them from a processing request.

The obtaining unit 401 obtains, for example, one or more samples of setting values related to an execution environment for parallel processing of DFT calculations for substances. For example, the obtaining unit 401 obtains one or more samples by receiving input of the one or more samples based on operation input from a user. For example, the obtaining unit 401 obtains one or more samples by receiving the one or more samples from another computer. The other computer is, for example, the client apparatus 202. For example, the obtaining unit 401 obtains one or more samples by extracting the one or more samples from a processing request.

The obtaining unit 401 obtains, for example, one or more candidates for setting values related to an execution environment for parallel processing of DFT calculations for substances. For example, the obtaining unit 401 obtains one or more candidates by receiving input of the one or more candidates based on operation input from a user. For example, the obtaining unit 401 obtains one or more candidates by receiving the one or more candidates from another computer. The other computer is, for example, the client apparatus 202. For example, the obtaining unit 401 obtains one or more candidates by extracting the one or more candidates from a processing request.

The obtaining unit 401 obtains, for example, a model expression corresponding to each of one or more calculation processes related to DFT calculation of a substance. For example, the obtaining unit 401 obtains the model expression by receiving input of the model expression based on an operational input from a user. For example, the obtaining unit 401 obtains the model expression by receiving the model expression from another computer. The other computer is, for example, the client apparatus 202. For example, the obtaining unit 401 obtains the model expression by extracting the model expression from a processing request.

The obtaining unit 401 may also receive a start trigger that starts the processing by one of the functional units. The start trigger may be, for example, a predetermined operational input by a user. The start trigger may be, for example, the reception of predetermined information from another computer. The start trigger may be, for example, the output of predetermined information by one of the functional units.

For example, the obtaining unit 401 regards obtaining one or more attribute values defining the DFT calculation and one or more samples of setting values related to the execution environment for parallel processing of the DFT calculation as a start trigger for starting the processing by the measuring unit 402 and the setting unit 403. For example, the obtaining unit 401 regards the obtaining of one or more candidates of setting values related to the execution environment for parallel processing of the DFT calculation for a substance as a start trigger for starting the processing by the calculating unit 404, the determining unit 405, and the executing unit 406.

The measuring unit 402 measures the actual value of the cost necessary to perform each calculation process related to the predetermined DFT calculation for the substance for each of the one or more samples obtained by the obtaining unit 401. The predetermined DFT calculation for the substance is set in advance by, for example, a user. The measuring unit 402 submits a job related to the predetermined DFT calculation for the substance to, for example, the execution environment indicated by each sample. The measuring unit 402 measures the actual cost of performing each calculation process related to a predetermined DFT calculation for a substance, for example, based on the results of executing the submitted job in the execution environment indicated by each sample. This allows the measuring unit 402 to obtain guidelines for generation of a model expression by the setting unit 403.

The measuring unit 402 measures the actual cost of performing each calculation process related to a DFT calculation for a substance for each of the one or more samples obtained by the obtaining unit 401, based on one or more attribute values obtained by the obtaining unit 401. The measuring unit 402 sets a DFT calculation for a substance, for example, based on one or more attribute values obtained by the obtaining unit 401. The measuring unit 402 submits a job related to the set DFT calculation, to the execution environment indicated by each sample. The measuring unit 402 measures the actual cost of performing each calculation process related to the set DFT calculation, for example, based on the results of executing the submitted job under the execution environment indicated by each sample. This allows the measuring unit 402 to obtain guidelines for generating a model expression by the setting unit 403.

The setting unit 403 generates a model expression corresponding to each calculation process related to the DFT calculation for the substance based on the actual measured values. For example, the setting unit 403 generates a model expression by setting parameters of the model expression corresponding to each calculation process based on the actual measured values using linear regression with the least squares method for each calculation process related to the DFT calculation for the substance. This allows the setting unit 403 to obtain guidelines for determining setting values by the determining unit 405.

The calculating unit 404 calculates the sum of costs corresponding to each of the one or more candidates obtained by the obtaining unit 401 based on the model expression corresponding to each calculation process related to the predetermined DFT calculation for the substance. The predetermined DFT calculation for the substance is set in advance by, for example, a user. For example, the calculating unit 404 inputs the candidate into a model expression corresponding to each calculation process for each of the one or more candidates obtained by the obtaining unit 401 and thereby obtains the cost output by the model expression. The calculating unit 404, for example, calculates the sum of costs corresponding to each candidate by adding up the obtained costs for each candidate. This allows the calculating unit 404 to obtain a guideline for determining a setting value by the determining unit 405.

The calculating unit 404 calculates the sum of costs corresponding to each of the one or more obtained candidates based on a model expression corresponding to each calculation process related to the DFT calculation for the substance, based on the one or more obtained attribute values. The calculating unit 404 sets a DFT calculation for the substance based on, for example, the one or more attribute values obtained by the obtaining unit 401. For example, the calculating unit 404 inputs each of the one or more candidates obtained by the obtaining unit 401 into a model expression corresponding to each calculation process related to the set DFT calculation, thereby obtaining a cost output by the model expression. The calculating unit 404, for example, calculates the sum of costs corresponding to each candidate by adding up the obtained costs for each candidate. This allows the calculating unit 404 to obtain a guideline for determining a setting value by the determining unit 405.

The determining unit 405 determines the setting value based on the calculated sum. For example, the determining unit 405 determines, as the setting value, one of the one or more candidates obtained by the obtaining unit 401, the one having the smallest calculated sum. For example, the determining unit 405 determines, as the setting value, one of the one or more candidates obtained by the obtaining unit 401, the one whose calculated sum is not more than a threshold. For example, the determining unit 405 determines, as the setting value, the statistical value of the candidate of the one or more candidates obtained by the obtaining unit 401, whose calculated sum is not more than a threshold. This allows the determining unit 405 to appropriately set the setting value in terms of the cost necessary for parallel processing of DFT calculations for the substance. Therefore, the determining unit 405 may easily reduce the cost necessary for parallel processing of DFT calculations for the substance.

For example, when the cost is an index value in which a larger value indicates a more favorable state, the determining unit 405 may determine, as the setting value, one of the one or more candidates obtained by the obtaining unit 401 whose calculated sum is the largest. For example, when the cost is an index value in which a larger value indicates a more favorable state, the determining unit 405 may determine, as the setting value, one of the one or more candidates obtained by the obtaining unit 401 whose calculated sum is equal to or greater than a threshold.

The executing unit 406 controls one or more processes or one or more threads within a process to perform parallel processing of DFT calculations for the substance based on the determined setting value. The process may be included in, for example, the information processing device 100. The process may be included in, for example, another computer. The other computer may be, for example, the parallel processing device 201.

For example, the executing unit 406 identifies a combination of the number A of processes and the number B of threads within a process based on the determined setting value. The executing unit 406 prepares an execution environment for parallel processing of DFT calculations for a substance, for example, by preparing the specified number A of processes including the specified number B of threads on one or more parallel processing devices 201. The executing unit 406 controls the prepared execution environment, for example, to process the DFT calculations for the substance in parallel under the prepared execution environment. The executing unit 406 obtains the results of parallel processing of the DFT calculations for the substance from the prepared execution environment. This allows the executing unit 406 to reduce the cost of parallel processing the DFT calculations for the substance.

The output unit 407 outputs the processing results of at least one of the functional units. The output format may be, for example, display on a display, print out to a printer, transmission to an external device via the network I/F 303, or storage in a storage area such as the memory 302 or the recording medium 305. This allows the output unit 407 to notify the user of the processing results of at least one of the functional units, thereby improving the convenience of the information processing device 100.

The output unit 407 outputs, for example, the setting values determined by the determining unit 405. For example, the output unit 407 outputs the setting values determined by the determining unit 405 so that the user may refer to the setting values. For example, the output unit 407 may transmit the setting values determined by the determining unit 405 to another computer. For example, the other computer is the client apparatus 202 or the like. This enables the output unit 407 to reduce the cost incurred when externally performing parallel processing of DFT calculations for substances.

The output unit 407 outputs, for example, the results of parallel processing of DFT calculations for substances obtained by the executing unit 406. For example, the output unit 407 outputs the results of parallel processing of DFT calculations for substances obtained by the executing unit 406 so that the user may refer to the results. For example, the output unit 407 may transmit the results of parallel processing of DFT calculations for substances obtained by the executing unit 406 to another computer. For example, the other computer is the client apparatus 202 or the like. As a result, the output unit 407 may make available the results of parallel processing of DFT calculations on a substance externally.

Here, while case has been described in which the information processing device 100 includes the obtaining unit 401, the measuring unit 402, the setting unit 403, the calculating unit 404, the determining unit 405, the executing unit 406, and the output unit 407, this is not a limitation. For example, the information processing device 100 may omit any of the functional units. For example, the information processing device 100 may omit the executing unit 406. In this case, the information processing device 100 may transmit the setting values determined by the determining unit 405 to another computer that includes the executing unit 406.

Next, an example of operation of the information processing device 100 will be described with reference to FIGS. 5 to 9.

FIGS. 5, 6, 7, 8, and 9 are explanatory diagrams depicting an example of operation of the information processing device 100. In FIGS. 5 to 9, the information processing device 100 searches for a machine setting 501 that minimizes an execution cost 504. The machine setting 501 is information that affects the processing time for the DFT calculation.

The machine setting 501 is, for example, a combination of the number of parallel processing devices 201, the number of processes, or the number of threads used when processing the DFT calculation in parallel. The parallel processing is, for example, MPI or OpenMP. The parallel processing may be, for example, a combination of MPI and OpenMP. The machine setting 501 may include, for example, the CPU clock frequency of the parallel processing device 201 or the number of accelerators used when processing the DFT calculation in parallel.

The execution cost 504 is, for example, the processing time for the DFT calculation. The execution cost 504 may be, for example, a node-time product or node time. A node is, for example, a computer that shares the DFT calculation. For example, the nodes are parallel processing devices 201.

For example, when DFT calculations are performed using the one or more parallel processing devices 201 that are supercomputers, the usage fee for the supercomputer tends to increase as the processing time for the DFT calculations increases. For this reason, it is desirable to search for the machine setting 501 that minimizes the execution cost 504.

First, for example, in FIG. 5, (5-1) the information processing device 100 receives input of multiple samples of the machine setting 501. The information processing device 100 receives input of, for example, N combinations (pᵢ,tᵢ) of the number of processes p and the number of threads t as multiple samples of the machine setting 501. i is an integer of 1, . . . , N. The lower limit of N depends on, for example, the number of values of parameters 512 of one or more sub-model expressions 511 that form the model 510.

The information processing device 100 receives input of a DFT setting 502. The DFT setting 502 includes, for example, atomic information. The atomic information includes, for example, the number of atoms. The atomic information includes, for example, the type of atom, basis function, potential, three-dimensional position, etc. for each atom. The DFT setting 502 includes, for example, lattice information. The lattice information includes, for example, lattice size, iteration boundary conditions, or symmetry. The DFT setting 502 includes, for example, functional information. The functional information includes, for example, the type of functional or parameters of a functional. The DFT setting 502 includes, for example, information concerning the SCF loop settings. The setting information includes, for example, the termination condition, the maximum iteration condition, the type of minimizer, and the type of preprocessing.

Based on the DFT setting 502 received as input, the information processing device 100 calculates the processing time necessary to perform each calculation process of the DFT calculation for each of the multiple samples for which input has been received. The information processing device 100 generates the sub-model expression 511 by setting the parameters 512 of the sub-model expression 511 corresponding to each calculation process based on a combination 503 of each sample and the processing time calculated for that sample.

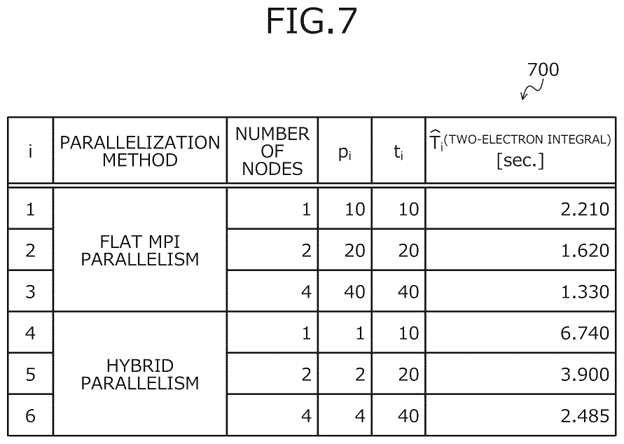

The sub-model expression 511 has a function of calculating the cost necessary to perform the calculation process. The information processing device 100 generates a model 510 by generating the sub-model expression 511. The model 510 has a function of calculating the sum of costs represented by the sub-model expression 511. A specific example of the information processing device 100 setting the parameters 512 will be described later with reference to FIG. 7. Next, with reference to FIG. 6, an example of the sub-model expression 511 will be described.

In FIG. 6, Table 600 depicts an example of the sub-model expression 511. Table 600 has fields for a sub-model s, a sub-model expression T^{(s)}(p,t;x^{(s)}), and a parameter x^{(s)}.

In the sub-model s field, the name of the calculation process corresponding to the sub-model s is set as a name for identifying the sub-model s. In the sub-model expression T^{(s)}(p,t;x^{(s)}), the mathematical expression T^{(s)}(p,t;x^{(s)}) that constitutes the sub-model expression 511 representing the sub-model s is set. p is the number of processes. t is the number of threads. In the x^{(s)} field, x^{(s)} is set as the parameter 512.

In Table 600, for convenience, x^{(s)} as the parameter 512 of each sub-model expression 511 is indicated using the same symbols a, b, c, and d, but the symbols a, b, c, and d indicating x^{(s)} as the parameters 512 of different sub-model expressions 511 are different values.

Here, the two-electron integral is, for example, a calculation process for calculating the Hartree-Fock exchange term of hybrid DFT. The two-electron integral includes, for example, a process parallel computational cost O(p⁻¹) or a thread parallel computational cost O(t⁻¹) for summation calculation. The computational cost is, for example, calculation time. For example, when a calculation with a fixed calculational complexity is divided into parts with no dependencies and processed in parallel on the basis of processes or threads, the calculation time is O(p⁻¹) or O(t⁻¹).

Furthermore, a potential integral is, for example, a calculation process for calculating the integral of a potential. The potential integral includes, for example, the computational cost of process parallelism, O(p⁻¹), and the communication cost of exchanging the calculation results between processes through all-to-all communication, O(p). The communication cost is, for example, communication time. For example, in a case where data with a fixed total size is exchanged between processes, when a one-dimensional torus is formed between the processes and messages, each of which has a size of O(p⁻¹), are communicated in p steps, the communication cost is O(p).

A sparse matrix multiplication is, for example, a calculation process for calculating the matrix multiplication of block sparse matrices. Sparse matrix multiplication is assumed to include, for example, the time O(logp) necessary to share sparse matrix information between processes using all-reduce communication, the computational cost of Cannon's algorithm O(t^{-1/2}p^{1/2}), and the communication cost O(p^{1/2}). For example, in a case where data of a fixed-size is shared between processes, when a binary tree is constructed between the processes and fixed-size messages are communicated in logp steps, the communication cost is O(logp).

Dense matrix multiplication is, for example, a calculation process for calculating the matrix multiplication of block dense matrices. Dense matrix multiplication is assumed to include, for example, the computational cost O(t^{-1/2}p^{1/2}) necessary for Cannon's algorithm and the communication cost O(p^{1/2}). For example, when calculating the multiplication of fixed-size block square matrices, the blocks are assumed to be evenly distributed and stored among two-dimensional processes. Here, the number of blocks in the row and column directions is O(p^{1/2}). The number of rows and columns in each block is O(p^{-1/2}). When a fixed communication cost is incurred for every O(p^{1/2}) steps, the total communication cost is O(p^{1/2}). When thread-parallel calculations are performed in O(t^{-1/2}) for every O(p^{1/2}) steps, the total computational cost is O(t^{-1/2}p^{1/2}).

Eigenvalue calculation is, for example, a calculation process that calculates the eigenvalues of a symmetric dense matrix. It is assumed that, for example, when the number of processes is equal to or greater than a certain number, the communication cost of broadcast communication from the root process to other processes becomes dominant, and the eigenvalue calculation includes a communication cost of O(logp). FFT is, for example, a calculation process that performs a 3D FFT or an inverse transform of a 3D FFT to calculate a plane wave. Similar to the potential integral, the FFT includes a process-parallel computational cost of O(p⁻¹) and a communication cost of O(p) for exchanging calculation results between processes via all-to-all communication.

Others are polynomials, such as computational costs of O(logp), O(p⁻¹), and O(t⁻¹). For example, the two-electron integral corresponds to “integrate_four_center” in the CP2K code. For example, the potential integral corresponds to “integrate_v_rspace” in the CP2K code. For example, the sparse matrix multiplication corresponds to “dbcsr_multiply_generic” in the CP2K code. For example, the dense matrix multiplication corresponds to “cp_gemm” in the CP2K code. For example, the eigenvalue calculation corresponds to cp_fm_syevd in the CP2K code. For example, the FFT corresponds to fft_wrap_pw1pw2 in the CP2K code.

The information processing device 100 may change or delete T^{(s)}(p,t;x^{(s)}) that forms any of the sub-model expressions 511 depicted in Table 600, based on, for example, a user's operational input. The information processing device 100 may change or delete x^{(s)} that forms the parameter 512 of T^{(s)}(p,t;x^{(s)}) that forms any of the sub-model expressions 511 depicted in Table 600, based on, for example, a user's operational input.

The information processing device 100 may also store a new sub-model expression 511 other than the sub-model expressions 511 depicted in Table 600, based on, for example, a user's operational input. When hybrid DFT is not taken into consideration, the information processing device 100 may omit storing the two-electron integral sub-model expression 511.

Next, with reference to FIG. 7, a specific example will be described in which the information processing device 100 sets x^{(s)} as the parameter 512 of T^{(s)}(p,t;x^{(s)}) which becomes the sub-model expression 511 corresponding to each calculation process based on multiple samples that have been received as input.

The information processing device 100 sets a DFT calculation based on the DFT setting 502 that has been received as input. The information processing device 100 performs the set DFT calculation for each (pᵢ,tᵢ) of {(pᵢ,tᵢ)}ᵢ₌₁^{N}. Here, the information processing device 100 may, for example, not perform the entire set DFT calculation, but perform only a part of the set DFT calculation. For example, when the DFT calculation involves repeating a predetermined operation X times, the information processing device 100 may repeat the predetermined operation only Y(<X) times.

The information processing device 100 measures the processing time {T\hat{ }ᵢ^{(s)}}_{s∈}s>0 necessary to perform the calculation process corresponding to sub-model s based on the results of the set DFT calculation. S is a set of sub-models s. The measurement may be implemented, for example, by an existing profiler, an existing performance counter, or an imperative statement manually inserted into the code of the DFT calculation software.

For example, when only a portion of the set DFT calculation is performed, the information processing device 100 may estimate the processing time {T\hat{ }ᵢ^{(s)}}_{s∈}s>0 required to perform the calculation process corresponding to sub-model s based on the results of the set DFT calculation. For example, the information processing device 100 estimates X/Y times the processing time corresponding to the calculation process corresponding to sub-model s when a predetermined operation is repeated Y times as the processing time {T\hat{ }ᵢ^{(s)}}_{s∈}s necessary to perform the calculation process corresponding to the sub-model s.

The information processing device 100 associates each (pᵢ,tᵢ) with {T\hat{ }ᵢ^{(s)}}_{s∈}s measured for that (pᵢ,tᵢ), and stores {(pᵢ,tᵢ, T\hat{ }ᵢ^{(s)}}ᵢ₌₁^{N}. The information processing device 100 sets the parameter x^{(s)} corresponding to each sub-model s by linear regression based on the stored {(pᵢ,tᵢ, T\hat{ }ᵢ^{(s)}}ᵢ₌₁^{N} for the sub-model s. At this time, when any of the parameters x^{(s)} has a negative value, the information processing device 100 may reset the value to 0.

Here, a specific example will be described where the information processing device 100 sets the parameter x^{(s)} of the two-electron integral sub-model s. For example, the information processing device 100 obtains {T\hat{ }ᵢ^{(two-electron integral)}}ᵢ₌₁⁶ for three (nᵢ,pᵢ,tᵢ) (i=1,2,3) related to flat MPI parallelism and three (nᵢ,pᵢ,tᵢ) (i=4,5,6) related to hybrid parallelism. The {T\hat{ }ᵢ^{(two-electron integral)}}ᵢ₌₁⁶ obtained by the information processing device 100 is depicted in Table 700.

ni is the number of nodes. nᵢ is 1, 2, or 4. Flat MPI parallelism is a format including one MPI process per core. Flat MPI parallelism is a format including, for example, 10 processes per node. Hybrid parallelism is a format including one MPI process per node and 10 threads per process.

Based on Table 700, the information processing device 100 sets parameter×^{(two-electron integral)}=(a^{(two-electron integral)}, b^{(two-electron integral)}, c^{(two-electron integral)})=(5.04,6.50, 1.05) using the least squares method. This allows the information processing device 100 to calculate T^{(two-electron integral)}(p,t;x^{(two-electron integral)}) for any (nᵢ,pᵢ,tᵢ). For example, for MPI parallelism, the information processing device 100 may calculate T^{(two-electron integral)} (80,80;x^{(two-electron integral)})=1.194 [s] for (8,80,80). Here, description with reference to FIG. 5 is continued.

In FIG. 5, (5-2) the information processing device 100 receives input of multiple candidates for the machine setting 501. For example, the information processing device 100 receives input of a set M of multiple combinations (p,t) of the number p of processes and the number t of threads as multiple candidates for the machine setting 501. For example, the information processing device 100 may receive input of a set M including all configurable combinations (p,t) as a population of targets for searching for the machine setting 501 that minimizes the execution cost.

Based on the generated model 510, the information processing device 100 calculates the sum Σ_{s∈}sT^{(s)} of T^{(s)}(p,t;x^{(s)}) corresponding to each combination (p,t) in M for which input has been received. Based on T^{(s)}(p,t;x^{(s)}) which constitutes the sub-model expression 511 that forms the model 510, the information processing device 100 calculates the sum Σ_{s∈}sT^{(s)} of T^{(s)}(p,t;x^{(s)}) corresponding to each combination (p,t) in M. The information processing device 100 calculates the execution cost 504 based on the calculated sum Σ_{s∈}sT^{(s)} for each combination (p, t).

For example, when the execution cost 504 is processing time, the information processing device 100 calculates the execution cost 504=Σ_{s∈}sT^{(s)}. For example, when the execution cost 504 is a node-time product, the information processing device 100 calculates the execution cost 504= (number of nodes)×Σ_{s∈}sT^{(s)}. For example, when the execution cost 504 is a usage fee, the information processing device 100 calculates the execution cost 504=(usage fee per unit node-time)×(number of nodes)×Σ_{s∈}sT^{(s)}.

The information processing device 100 determines one of the combinations (p,t) in M as the machine setting 501 based on the calculated execution cost 504. For example, the information processing device 100 determines the combination (p,t) that minimizes the calculated execution cost 504 as the machine setting 501.

Here, a specific example will be described where the information processing device 100 determines the machine setting 501. Here, it is assumed that the DFT calculation includes calculation processes of the two-electron integral and other calculation processes. Let x^{(other)}=(0.198, 0.401, 0.502, 0, 0.569). Let M= {(in, 10n)|n=10, 11, . . . ,40, i=1, 2, 5, 10}. M represents the cases where the number of nodes is n, the number of processes in the node is i, and the number of threads in the process is 10/i. For example, the information processing device 100 identifies (p,t)=(31,310) for which T^{(s)}=1.984 as (p,t)∈M for which Σ_{s∈}sT^{(s)}=T^{(two-electron integral)}+T^{(other)} is smallest, and determines this as the machine setting 501.

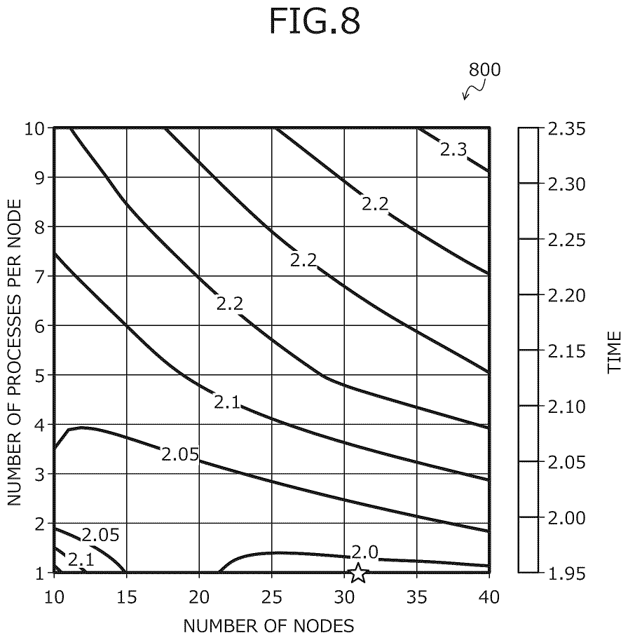

This enables the information processing device 100 to determine the machine setting 501 that allows efficient parallel processing of DFT calculations. The information processing device 100 utilizes the polynomial sub-model expression 511 and therefore, may efficiently determine the machine settings 501. Next, description is given with reference to FIG. 8, which depicts an example of the distribution of Σ_{s∈}sT^{(s)}.

In FIG. 8, Graph 800 depicts the distribution of Σ_{s∈}sT^{(s)}. Graph 800 depicts, for example, the contour lines of Σ_{s∈}sT^{(s)}. For example, Graph 800 depicts the distribution of Σ_{s∈}sT^{(s)} in the above case where the DFT calculation includes calculation processes of the two-electron integral and other calculation processes.

A horizontal axis of Graph 800 indicates, for example, the number of nodes. A vertical axis of Graph 800 indicates the number of processes per node. The star-shape on Graph 800 indicates the point where Σ_{s∈}sT^{(s)} is smallest. As depicted in Graph 800, Σ_{s∈}sT^{(s)} is not proportional to the number of nodes or the number of processes.

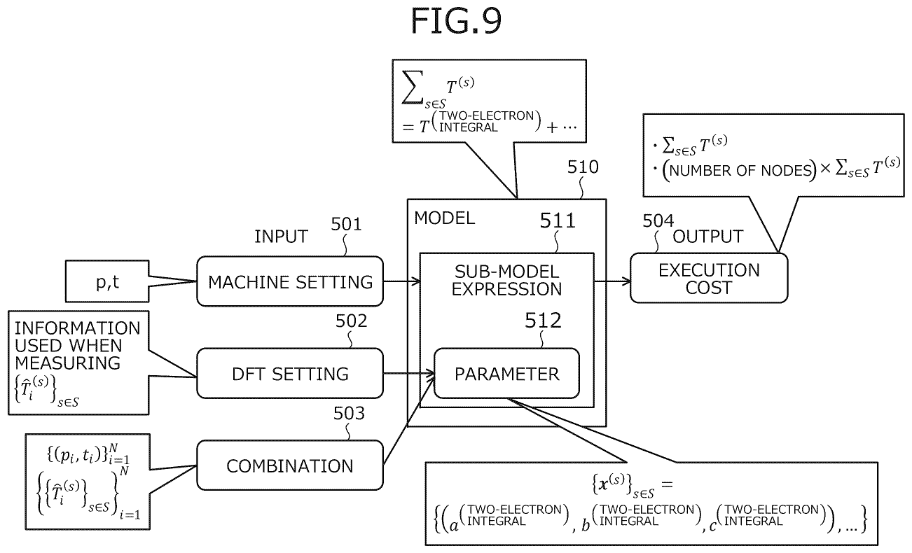

In contrast to this, the information processing device 100 may determine an appropriate machine setting 501 by taking Σ_{s∈}sT^{(s)} into consideration. Next, with reference to FIG. 9, specific definitions of each element depicted in FIG. 5 will be summarized. The elements are, for example, the machine setting 501, the DFT setting 502, the combination 503, the execution cost 504, the model 510, the sub-model expression 511, and the parameters 512.

FIG. 9 depicts specific definitions of each element depicted in FIG. 5. As depicted in FIG. 9, the machine setting 501 is, for example, p and t. The DFT setting 502 is, for example, information used to measure {T\hat{ }ᵢ^{(s)}} and is information for setting the DFT calculation.

The combination 503 is, for example, a combination of {(pᵢ,tᵢ)}ᵢ₌₁^{N} and {{T\hat{ }ᵢ^{(s)}}_{s∈}s}ᵢ₌₁^{N}. The execution cost 504 is, for example, Σ_{s∈}sT^{(s)} or (number of nodes)×Σ_{s∈}sT^{(s)}.

The sub-model expression 511 is, for example, T^{(s)}(p,t;x^{(s)}). The sub-model expression 511 is used, for example, when calculating Σ_{s∈}sT^{(s)}=(T^{(two-electron integral)}+ . . . +T^{(other)}). The parameters 512 are, for example, {x^{(s)}}_{s∈}s={(a^{(two-electron integral)}, b^{(two-electron integral)}, c^{(two-electron integral)}), . . . (a^{(other)}, b^{(other)}, c^{(other)}, d^{(other)})}. The model 510 is, for example, Σ_{s∈}sT^{(s)}=(T^{(two-electron integral)}+ . . . +T^{(other)})

As described, the information processing device 100 may determine an appropriate machine setting 501 for a certain DFT setting 502. The information processing device 100 may reduce the execution cost incurred when processing DFT calculations in parallel.

When changing the DFT setting 502, the information processing device 100 regenerates the sub-model expression 511 and then determines the appropriate machine setting 501 again.

In this case, the information processing device 100 may regenerate the sub-model expression 511 even when the DFT calculation set based on the changed DFT setting 502 is interrupted before completion. For example, when the DFT calculation set based on the changed DFT setting 502 involves repeating predetermined operation X times, the information processing device 100 may repeat the predetermined operation only Y(<X) times and regenerate the sub-model expression 511. Therefore, even when the DFT setting 502 is changed, the information processing device 100 may easily re-determine the appropriate machine setting 501.

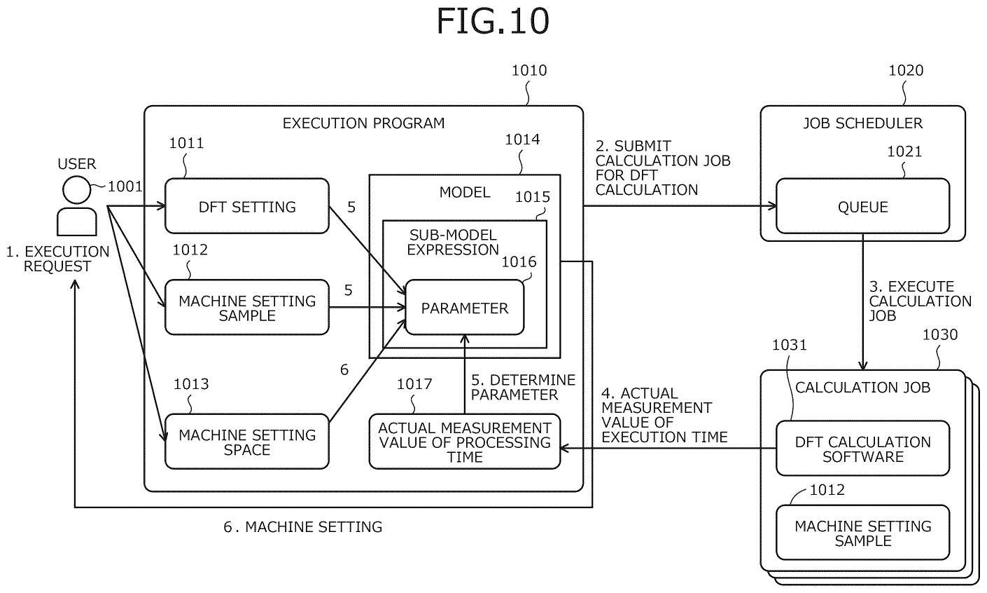

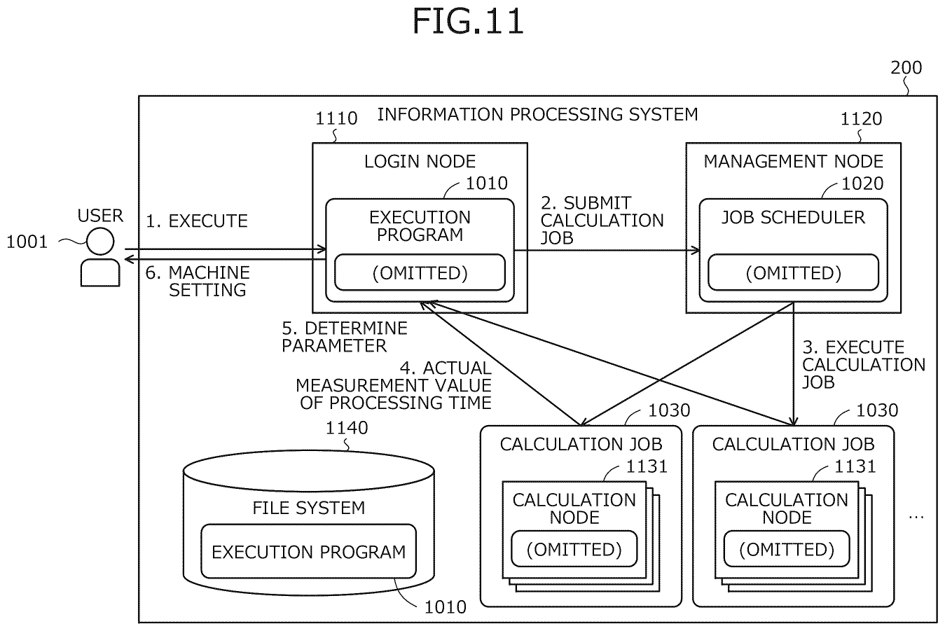

Next, a specific example of the operation of the information processing device 100 will be described with reference to FIGS. 10 and 11.

FIGS. 10 and 11 are explanatory diagrams depicting a specific example of the operation of the information processing device 100. In FIG. 10, an execution program 1010 and a job scheduler 1020 exist. The execution program 1010 is executed by, for example, the information processing device 100. The job scheduler 1020 is executed by, for example, the information processing device 100.

(10-1) A user 1001 executes the execution program 1010. The user 1001 issues an execution request to the execution program 1010, for example, via a client apparatus 202, the execution request including a DFT setting 1011, one or more machine setting samples 1012, and a machine setting space 1013. The client apparatus 202 transmits the execution request, including the DFT setting 1011, the one or more machine setting samples 1012, and the machine setting space 1013, to the information processing device 100, based on, for example, an operation input by the user 1001.

The DFT setting 1011 is information that specifies a DFT calculation. Each of the one or more machine setting samples 1012 indicates an example of a machine setting used when determining parameters 1016 of a sub-model expression 1015 that forms a model 1014. The samples 1012 are {(pᵢ, tᵢ)}ᵢ₌₁^{N}. The machine setting space 1013 indicates a target population for searching for a machine setting that minimizes the execution cost.

(10-2) The execution program 1010 is started in response to an execution request. The execution program 1010 obtains the DFT setting 1011, the one or more machine setting samples 1012, and the machine setting space 1013 from the execution request. The execution program 1010 sets the content of the DFT calculation based on the DFT setting 1011. The execution program 1010 generates a group of calculation jobs 1030 corresponding to each of the one or more machine setting samples 1012 based on the set content of the DFT calculation. The calculation job 1030 may include, for example, a sample 1012 corresponding to the calculation job 1030 itself. The execution program 1010 associates a group of calculation jobs 1030 corresponding to each sample 1012 with the sample 1012 and submits the group of calculation jobs 1030 corresponding to the sample 1012 to the job scheduler 1020.

(10-3) The job scheduler 1020 has a queue 1021. The job scheduler 1020 temporarily stores the submitted group of calculation jobs 1030 in the queue 1021. The job scheduler 1020 sequentially retrieves and executes the calculation jobs 1030 from the queue 1021. The job scheduler 1020, for example, assigns the calculation job 1030 to any of the parallel processing devices 201 in cooperation with the job scheduler 1020 and executes the calculation job 1030.

(10-4) The calculation job 1030 includes a DFT calculation software 1031. The calculation job 1030 performs DFT calculation using the DFT calculation software 1031. The calculation job 1030 transmits actual measurement values 1017 of the processing time necessary to perform each calculation process of the DFT calculation to the execution program 1010. (10-5) The execution program 1010 receives the actual measurement values 1017 of the processing time necessary to perform each calculation process of the DFT calculation from the calculation job 1030. The execution program 1010 determines the sub-model expression 1015 by determining {x^{(s)}} ses as the parameter 1016, based on the combination {T\hat{ }ᵢ^{(s)}}_{s∈}s}=ᵢ₌₁^{N} of the actual measurement values 1017 of the processing times. The execution program 1010 generates the model 1014 by determining the sub-model expression 1015.

(10-6) The execution program 1010 determines the machine setting (p,t) from the space 1013 of machine settings that minimizes the total sum of the costs represented by the sub-model expression 1015. The execution program 1010 outputs the determined machine settings (p,t) so that the user 1001 may refer to the settings. This allows the execution program 1010 to make the appropriate machine settings (p,t) available to the user 1001. Next, description is given with reference to FIG. 11, which describes how the execution program 1010, the job scheduler 1020, and calculation job 1030 correspond to hardware.

In FIG. 11, the execution program 1010 is stored in, for example, a file system 1140. The file system 1140 is, for example, implemented by the information processing device 100. The execution program 1010 is executed by, for example, a login node 1110. The login node 1110 is, for example, implemented by the information processing device 100. The login node 1110 may be, for example, implemented by the information processing device 100 and the client apparatus 202.

The job scheduler 1020 is executed by, for example, a management node 1120. The management node 1120 is, for example, implemented by the information processing device 100 or the parallel processing device 201. The calculation job 1030 is executed by the management node 1120 and the calculation node 1131. The calculation node 1131 is implemented by, for example, the parallel processing device 201. The login node 1110, the management node 1120, the calculation node 1131, and the file system 1140 may be implemented by, for example, a single supercomputer.

Here, data exchange between the execution program 1010 and the calculation node 1131 may be implemented via the job scheduler 1020 or a shared file system. Furthermore, the calculation jobs 1030 corresponding to each sample 1012 may be executed simultaneously. The calculation node 1131 may also include an existing profiler or an existing performance counter.

The execution program 1010 may control the job scheduler 1020 and the calculation node 1131 to process the DFT calculation in parallel based on the determined machine settings (p,t). For example, the execution program 1010 generates a group of calculation jobs 1030 for parallel processing of the DFT calculation based on the determined machine settings (p,t) and submits the group of calculation jobs 1030 to the job scheduler 1020. This allows the execution program 1010 to reduce the execution cost incurred when processing the DFT calculation in parallel.

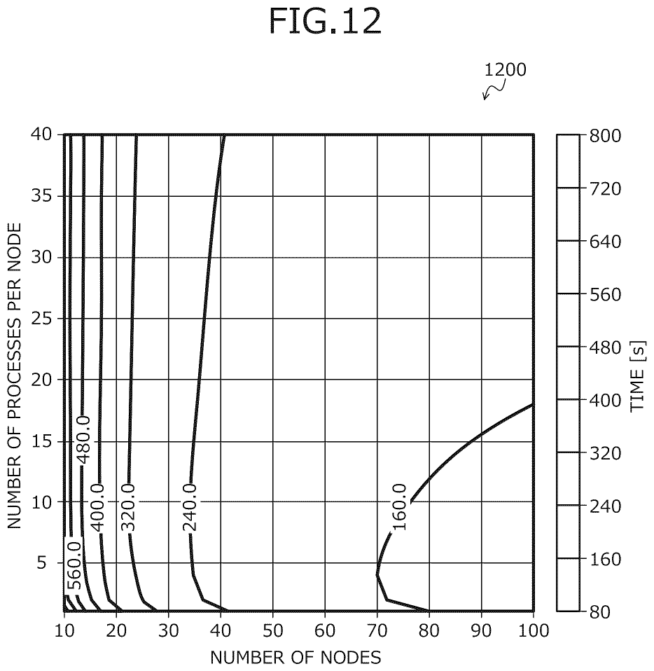

Next, an embodiment of the information processing device 100 will be described with reference to FIG. 12.

FIG. 12 is an explanatory diagram depicting an embodiment of the information processing device 100. In FIG. 12, the information processing device 100 searches for appropriate machine settings for implementing CP2K on the ABCI supercomputer. The DFT settings specify, for example, a hybrid DFT calculation of 52 atoms of Sr—Fe—O using the PBE functional.

The multiple machine setting samples include, for example, five samples with the number of nodes being 4, 8, 16, 32, or 64, the number of processes per node being 2, and the number of threads per node being 40. The multiple machine setting samples include, for example, three samples with the number of nodes being 16, the number of processes per node being 1, 4, or 10, and the number of threads per node being 40. The actual processing time is measured using the CP2K time measurement function.

In FIG. 12, Graph 1200 depicts the distribution of Σ_{s∈}sT^{(s)}. Graph 1200 depicts, for example, the contour lines of Σ_{s∈}sT^{(s)}. The horizontal axis of Graph 1200 indicates, for example, the number of nodes. The vertical axis of Graph 1200 indicates the number of processes per node.

As depicted in Graph 1200, Σ_{s∈}sT^{(s)} is not proportional to the number of nodes or the number of processes. For example, in the range where the number of nodes is less than 20, the larger the number of processes per node, the smaller the execution cost tends to be. However, in the range where the number of nodes is 20 or more, the larger the number of processes per node, the larger the execution cost tends to be. For example, as the number of nodes increases, factors such as the computational cost O(p^{1/2}) of sparse matrix multiplication, which has a positive correlation with the number of processes, are thought to be more likely to affect the execution cost.

Here, when the number of nodes is 100, the number of threads per node is 40, and the number of processes is 1, 2, 4, 5, 8, 10, 20, or 40, the information processing device 100 determines the machine setting to (p,t)=(200,4000). When (p,t)=(200,4000), the execution cost is 136.9 [s].

For comparison, when (p,t)=(100,4000), which represents a case where the number of processes per node is 1, the execution cost is 142.9 [s]. For comparison, when (p,t)=(4000,4000), which represents a case where the number of processes per node is 40, the execution cost is 192.7 [s].

Thus, the information processing device 100 may determine a machine setting that may speed up DFT calculations by 1.04 times compared to when the number of processes per node is 1. The information processing device 100 may determine a machine setting that may speed up DFT calculations by 1.41 times compared to when the number of processes per node is 40.

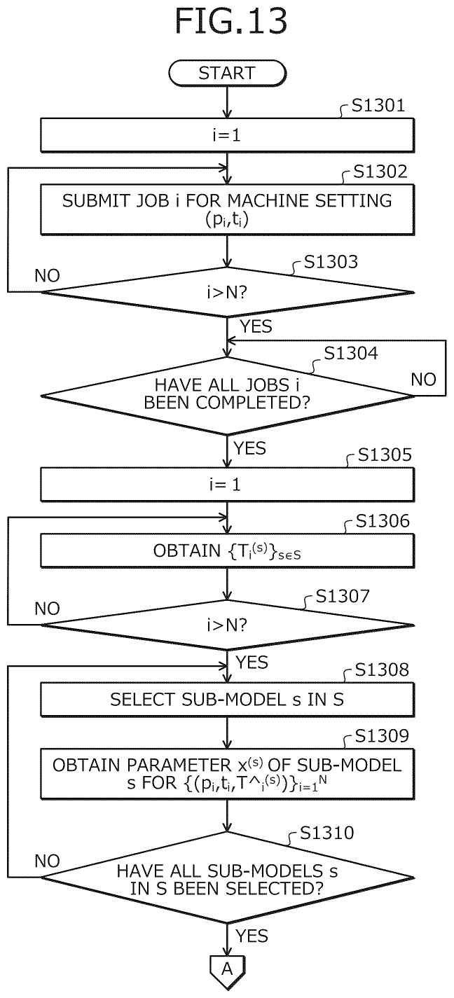

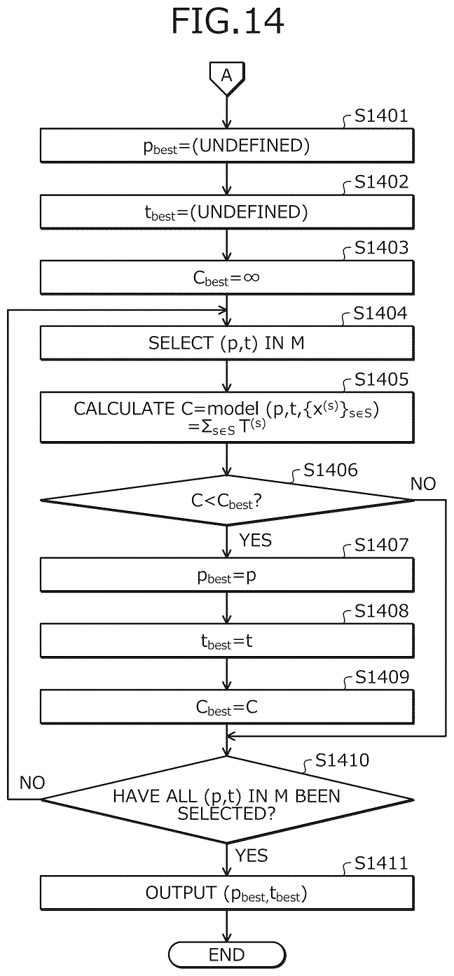

Next, an example of an overall processing procedure executed by the information processing device 100 will be described with reference to FIGS. 13 and 14. The overall processing is implemented, for example, by the CPU 301 depicted in FIG. 3, storage areas such as the memory 302 and the recording medium 305, and the network I/F 303.

FIGS. 13 and 14 are flowcharts depicting an example of the overall processing procedure. In FIG. 13, the information processing device 100 sets i=1 (step S1301). Then, the information processing device 100 proceeds to the process at step S1302.

At step S1302, the information processing device 100 submits job i to the machine setting (pᵢ,tᵢ) (step S1302).

Then, the information processing device 100 determines whether i>N is satisfied (step S1303). If i>N is not true (step S1303: NO), the information processing device 100 increments i and returns to the process at step S1302. On the other hand, if i>N is true (step S1303: YES), the information processing device 100 proceeds to the process at step S1304.

At step S1304, the information processing device 100 determines whether all submitted jobs i have been completed (step S1304). If an uncompleted job i remains (step S1304: NO), the information processing device 100 returns to the process at step S1304. On the other hand, when all submitted jobs i have been completed (step S1304: YES), the information processing device 100 proceeds to the process at step S1305.

At step S1305, the information processing device 100 sets i=1 (step S1305). Then, the information processing device 100 proceeds to the process at step S1306.

At step S1306, the information processing device 100 obtains {T\hat{ }ᵢ^{(s)}}_{s∈}s based on the result of execution of the job i (step S1306).

Then, the information processing device 100 determines whether i>N is satisfied (step S1307). Here, when i>N is not true (step S1307: NO), the information processing device 100 increments i and returns to the process at step S1306. On the other hand, when i>N is true (step S1307: YES), the information processing device 100 proceeds to the process at step S1308.

At step S1308, the information processing device 100 selects a sub-model s in S (step S1308). Next, the information processing device 100 obtains the parameter x^{(s)} of the selected sub-model s by a linear regression for {(pᵢ,tᵢ, T\hat{ }ᵢ^{(s)}}ᵢ₌₁^{N} (step S1309).

Then, the information processing device 100 determines whether all sub-models s in S have been selected (step S1310). Here, when there is a sub-model s that has not yet been selected (step S1310: NO), the information processing device 100 returns to the process at step S1308. On the other hand, when all sub-models s in S have been selected (step S1310: YES), the information processing device 100 proceeds to the process at step S1401 in FIG. 14.

In FIG. 14, the information processing device 100 sets pbest= (undefined) (step S1401). Next, the information processing device 100 sets t_{best}=(undefined) (step S1402). Then, the information processing device 100 sets C_{best}=∞ (step S1403). After that, the information processing device 100 proceeds to the process at step S1404.

At step S1404, the information processing device 100 selects (p,t) in M (step S1404). Next, the information processing device 100 calculates C=model (p,t,{x^{(s)}}_{s∈}s)=Σ_{s∈}s T^{(s)} (step S1405).

Then, the information processing device 100 determines whether C<Cbest is satisfied (step S1406). Here, when C<C_{best} is true (step S1406: YES), the information processing device 100 proceeds to the process at step S1407. On the other hand, when C<C_{best} is not true (step S1406: NO), the information processing device 100 proceeds to the process at step S1410.

At step S1407, the information processing device 100 sets p_{best}=p (step S1407). Next, the information processing device 100 sets t_{best}=t (step S1408). Then, the information processing device 100 sets C_{best}=C (step S1409). After that, the information processing device 100 proceeds to the process at step S1410.

At step S1410, the information processing device 100 determines whether all of (p,t) in M have been selected (step S1410). Here, when there are any (p,t) that have not yet been selected (step S1410: NO), the information processing device 100 returns to the process at step S1404. On the other hand, when all of (p,t) in M have been selected (step S1410: YES), the information processing device 100 proceeds to the process at step S1411.

At step S1411, the information processing device 100 outputs (p_{best}, t_{best}) (step S1411). Then, the information processing device 100 ends the overall processing. As a result, the information processing device 100 may find (p,t) within M for which the total cost C is smallest.

Here, the information processing device 100 may execute some steps of the flowcharts in FIGS. 13 and 14 in a reversed order. For example, the order of steps S1401 and S1402 may be reversed. Furthermore, the information processing device 100 may omit some steps of the flowcharts in FIGS. 13 and 14. For example, when the parameter x^{(s)} of the sub-model s is known, the processes at steps S1301 to S1310 may be omitted.

As described above, the information processing device 100 may obtain one or more candidate setting values related to the execution environment for parallel processing of density functional theory calculations for a substance. The information processing device 100 may store a model expression corresponding to each of one or more calculation processes related to density functional theory calculations for a substance, the model expression outputting an estimated value of the cost necessary to perform the calculation process in response to input setting values. The information processing device 100 may calculate a sum of costs corresponding to each of one or more obtained candidates based on the model expression. The information processing device 100 may determine a setting value based on the calculated sum. This allows the information processing device 100 to determine appropriate setting values to reduce the cost necessary to perform parallel processing of density functional theory calculations for a substance.

The information processing device 100 may measure actual measurements of the cost necessary to perform each of one or more calculation processes for each of one or more samples of setting values. The information processing device 100 may set parameters of a model expression corresponding to each of one or more calculation processes, the model expression outputting an estimated value of the cost necessary to perform the calculation process in response to input setting values, based on the measured actual measurements. This allows the information processing device 100 to generate a model expression. The information processing device 100 may eliminate the need to prepare a model expression in advance.

The information processing device 100 may obtain one or more attribute values that define density functional theory calculations for a substance. The information processing device 100 may measure the actual cost of performing each of one or more calculation processes for each of one or more samples of setting values based on the obtained one or more attribute values. This allows the information processing device 100 to determine appropriate setting values in accordance with the obtained one or more attribute values.

The information processing device 100 may employ, as setting values, information that defines the number of processes that share the density functional theory calculations for a substance and the number of threads that each process has. This allows the information processing device 100 to determine appropriate setting values that define the number of processes and the number of threads.

The information processing device 100 may employ, as attribute values, the type of atoms that form a substance, the number of atoms that form a substance, or the positions of atoms that form a substance. According to the information processing device 100, the attribute values may be the type of density functional for a substance, the type of basis function used in the density functional for a substance, or the termination condition for density functional theory calculations for a substance. This allows the information processing device 100 to appropriately define density functional theory calculations.

The information processing method described in the present embodiment may be implemented by executing a prepared program on a computer such as a personal computer and a workstation. The program is stored on a non-transitory, computer-readable recording medium such as a hard disk, a flexible disk, a compact disc read-only memory (CD-ROM), a magneto-optical (MO) disc, and a digital versatile disc (DVD), read out from the computer-readable medium, and executed by the computer. The program may be distributed through a network such as the Internet.

According to one aspect, it becomes possible to reduce the cost incurred when parallel processing density functional theory calculations for a substance.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A computer-readable recording medium storing therein an information processing program causing a computer to execute a process, the process comprising:
obtaining one or more candidates for a setting value related to an execution environment for parallel processing of a density functional theory calculation for a substance;
calculating a sum of costs for each of the obtained one or more candidates, the sum of costs being calculated based on one or more model expressions that, respectively, correspond to one or more calculation processes related to the density functional theory calculation and that, respectively, output an estimated value of a cost incurred when a corresponding one of the one or more calculation processes is performed in response to input of the setting value; and
determining the setting value based on the sum calculated for the each of the obtained one or more candidates.

2. The computer-readable recording medium according to 1, wherein the determining includes determining, as the setting value, a candidate whose calculated sum is a smallest among the one or more candidates or whose calculated sum is not more than a threshold.

3. The computer-readable recording medium according to 1, the process further comprising:
measuring an actual value of the cost incurred when performing each of the one or more calculation processes for each of one or more samples of the setting value; and
setting one or more parameters of the one or more model expressions, based on the measured actual value.

4. The computer-readable recording medium according to 3, the process further comprising:
obtaining one or more attribute values that define the density functional theory calculation for the substance, wherein
the measuring includes measuring the actual value of the cost incurred, based on the obtained one or more attribute values.

5. The computer-readable recording medium according to 1, wherein
the setting value is information that specifies a number of processes sharing the density functional theory calculation for the substance and a number of threads that each of the processes has.

6. The computer-readable recording medium according to 4, wherein
the one or more attribute values include at least any of types of atoms forming the substance, a number of atoms forming the substance, positions of atoms forming the substance, a type of a density functional for the substance, a type of a basis function used for the density functional for the substance, and a termination condition for the density functional theory calculation for the substance.

7. The computer-readable recording medium according to 1, the process further comprising:
controlling the execution environment represented by the determined setting value so as to perform the density functional theory calculation for the substance in parallel.

8. An information processing method executed by a computer, the method comprising:
obtaining one or more candidates for a setting value related to an execution environment for parallel processing of a density functional theory calculation for a substance;
calculating a sum of costs for each of the obtained one or more candidates, the sum of costs being calculated based on one or more model expressions that, respectively, correspond to one or more calculation processes related to the density functional theory calculation and that, respectively, output an estimated value of a cost incurred when a corresponding one of the one or more calculation processes is performed in response to input of the setting value; and
determining the setting value based on the sum calculated for the each of the obtained one or more candidates.

9. An information processing device, comprising:
a memory;
a processor coupled to the memory, the processor configured to:
obtain one or more candidates for a setting value related to an execution environment for parallel processing of a density functional theory calculation for a substance;
calculate a sum of costs for each of the obtained one or more candidates, the sum of costs being calculated based on one or more model expressions that, respectively, correspond to one or more calculation processes related to the density functional theory calculation and that, respectively, output an estimated value of a cost incurred when a corresponding one of the one or more calculation processes is performed in response to input of the setting value; and
determine the setting value based on the sum calculated for the each of the obtained one or more candidates.
